(19) United States
(12) Patent Application Publication
(10) Pub. No.: US 2025/0279790 A1
(43) Pub. Date: Sep. 4, 2025

(54) Method and Device for Converting Representations of Values in Different Systems

(71) Applicant: Huawei Technologies Co., Ltd., Shenzhen (CN)

(72) Inventors: Vitaly Vitalyevich Slobodskoy, Nizhny Novgorod (RU); Erik Konstatin Plesner, Nizhny Novgorod (RU); Oleg Vasilyevich Ignatov, Nizhny Novgorod (RU); Roman Alekseevich Kurmaev, Moscow (RU); Valeria Georgievna Ryabchikova, Nizhny Novgorod (RU); Elizaveta Robertovna Martirosyan, Nizhny Novgorod (RU)

(21) Appl. No.: 19/208,297

(22) Filed: May 14, 2025

Related U.S. Application Data
(63) Continuation of application No. PCT/RU2022/000337, filed on Nov. 15, 2022.

(51) Int. Cl. H03M 7/18

(52) U.S. Cl. CPC H03M 7/18

(57) ABSTRACT

Embodiments of the present application provide a method and a device for converting representations of values between RNS and CRNS. The present application can be used in any product to which RNS is applied. A compact RNS (called CRNS) is proposed by the present application, and a bijection between RNS representations and CRNS representations is created. The bijection maps between (n+1)-bit RNS representations and n-bit CRNS representations by using a logic function. The bijection maps only 2ⁿ values corresponding to an n-bit BNS value in a dynamic range [0, 2ⁿ−1].

### CROSS-REFERENCE TO RELATED APPLICATIONS

This application is a continuation of International Application No. PCT/RU2022/000337, filed on Nov. 15, 2022, the disclosure of which is hereby incorporated by reference in its entirety.

### TECHNICAL FIELD

Embodiments of the present invention relate to the field of residual number system (RNS), and more specifically, to a method and device for converting representations of values in different systems. cl BACKGROUND

A residual number system (RNS) is a number representation system, which can obtain a set of remainders of a value by performing remainder operations on a set of moduli. The dynamic range [0; M−1] is the number of values which have a unique representation in the RNS. M is the product of all the moduli of the RNS. There is no weight and propagation between channels corresponding to each remainder. Using the RNS, an operation of a value with a long bit width can be converted into an operation of a set of remainders with a shorter bit width of the value. Hardware resources and delay required for a single operation are smaller compared to a binary number system (BNS), and parallelism of the operation is improved. In addition, the hardware resources can also be saved. The RNS is widely used after several years of development because of these properties.

It is known that a representation of a value in the BNS is different from a representation of the value in the RNS, and the representation in the RNS is related to the moduli of the RNS. Consider an n-bit BNS, and the BNS has a dynamic range of 2ⁿ, that is, the n-bit BNS can represent 2ⁿ values in total, namely the values [0; 2ⁿ−1]. It requires an RNS of at least n+1 bits to represent a BNS with a dynamic range of 2ⁿ. This difference between the representation of the value in the BNS and the representation of the value in the RNS brings many disadvantages to the application of the RNS, for an example, a conversion between the BNS representation and the RNS representation will lead to excessive storage overhead and memory bandwidth overhead

### SUMMARY

Embodiments of the present application provide a method for converting representations of values in different systems, which can reduce storage consumption and memory bandwidth.

According to a first aspect, provided is a method for converting representations of values in different systems, including:
receiving a first representation of a first value, where the first representation is a representation of the first value in a residual number system (RNS), and the first representation contains n+1 bits;
converting the first representation to a second representation according to a truncated bit, where the second representation is a representation of the first value in a compact residual number system (CRNS), and the second representation contains n bits,
where the truncated bit is any one of the n+1 bits, and if the truncated bit of the n+1 bits is equal to zero, the second representation is a copy of remaining bits of the n+1 bits contained in the first representation that exclude the truncated bit, and if the truncated bit of the n+1 bits is equal to one, the second representation is a copy of recoded remaining n bits of the n+1 bits contained in the first representation that exclude the truncated bit;
where the first value is one of 2ⁿ values, the 2ⁿ values can be represented by an n-bit BNS, and a value range of the 2ⁿ values is [0; 2ⁿ−1], n is an integer.

According to the present application, a compact RNS (called CRNS in the present application) is proposed, and the n+1-bit RNS representations and n-bit CRNS representations can be converted to each other. By storing n-bit CRNS representations, compared to storing n+1-bit RNS representations, the storage consumption is reduced.

In addition, the inconvenience of converting between n+1-bit RNS representations and n-bit BNS values can be resolved, and the power consumption is reduced.

According to a second aspect, provided is a method for converting representations of values in different systems, including:
receiving a second representation of a first value, where the second representation is a representation of the first value in a compact residual number system (CRNS), and the second representation contains n bits;
determining whether the second representation is identical in the CRNS and an RNS;
converting the second representation to a first representation, where the first representation is a representation of the first value in the RNS, and the first representation contains n+1 bits;
where if the second representation is identical in the CRNS and the RNS, the first representation is a copy of the n bits of the second representation and a truncated bit added by zero, and if the second representation is different in the CRNS and the RNS, the first representation is a copy of recoded n bits of the second representation and the truncated bit added by one;
where the first value is one of 2ⁿ values, the 2ⁿ values can be represented by an n-bit BNS, and a value range of the 2ⁿ values is [0; 2ⁿ−1], n is an integer.

The technique effect of the method of the second aspect could refer to that of the first aspect, and is not repeated here.

In an embodiment of the first aspect or the second aspect, where the 2ⁿ values correspond to 2ⁿ first representations in the RNS, the 2ⁿ values correspond to 2ⁿ second representations in the CRNS, and the 2ⁿ first representations and the 2ⁿ second representations are in a bijection mapping relationship.

According to this embodiment, a bijection between RNS representations and CRNS representations is created. Specifically, the bijection maps between (n+1)-bit RNS representations and n-bit CRNS representations by using a logic function. The bijection maps only 2ⁿ values corresponding to an n-bit BNS value in a range [0, 2ⁿ−1]. The BNS values larger than or equal to 2ⁿ are disregarded, and these BNS values will not be used and are not needed. The bijection allow using only n bits to represent all 2ⁿ BNS values of an n-bit BNS. Comparing with storing (n+1)-bit RNS representations of values, the storage consumption is reduced by storing n-bit CRNS representations.

Consider an n-bit BNS, and the BNS has a dynamic range of 2ⁿ. It has been proved by the present application that, an RNS representation of a BNS value in the dynamic range [0; 2ⁿ−1] will always require at least n+1 bits. Conversion between n-bit BNS representations and (n+1)-bit RNS representations leads to memory storage consumption, for example, an 8-bit BNS representation becomes a 9-bit RNS representation, and actually takes up 2 pcs of 8-bit positions in memory. It requires more memory space to store RNS representations than BNS representations. The proposed solution by the present application allows to use n-bit CRNS representation to map an n-bit BNS representation, hence the memory consumption is reduced.

In an embodiment of the first aspect or the second aspect, where the 2ⁿ first representations include f first representations of a first type and (2ⁿ−f) first representations of a second type, the truncated bit of the first representation of the first type is equal to one, and the truncated bit of the first representation of the second type is equal to zero;
where the f first representations of the first type correspond to f second representations, and each of the f second representations is a copy of recoded remaining n bits of the corresponding first representation of the first type that exclude the truncated bit;
where the (2ⁿ−f) first representations of the second type correspond to (2ⁿ−f) second representations, and each of the (2ⁿ−f) second representations is a copy of the remaining n bits of the corresponding first representation of the second type that exclude the truncated bit.

In an embodiment of the first aspect or the second aspect, the bijection mapping relationship between the f first representations of the first type and the f second representations is adjustable.

According to this embodiment, the actual CRNS values do not matter. The only thing which matters, is that the mapping is a bijection. In order to do logic optimization, only the recoded RNS representations are permutated, and the RNS representations which are “copied” are not permutated. By doing so, the hardware complexity of the conversions between RNS and CRNS is reduced.

In an embodiment of the first aspect or the second aspect, where the n+1 bits of the first representation contain k parts, the k parts are residuals corresponding to the k moduli of the RNS, and the k parts are arranged in one of the following orders:
in an ascending order according to corresponding values of the k moduli;
in a descending order according to corresponding values of the k moduli; or
in a random order.

In an embodiment of the first aspect or the second aspect, the n+1 bits of the k parts are interleaved, and the truncated bit is one of the interleaved n+1 bits.

In an embodiment of the first aspect or the second aspect, where the k parts contain a first part, and the first part contains pᵢ bits, the truncated bit is any one of the pᵢ bits, pᵢ=[log₂(mi−1)], mᵢ is a modulo of the k moduli corresponding to the first part, and the first part is any one of the k parts, 1≤i≤k, i and k are integers.

In an embodiment of the first aspect or the second aspect, where the truncated bit is a most significant bit (MSB) of the pᵢ bits.

According to this embodiment, use of the MSB of the truncated modulo as the truncated bit usually leads to fewer RNS representations with the RNSⱼ=1, that is, the number of the RNS representations needs to be recoded is reduced. The storage area, power consumption and latency for conversion are reduced.

In an embodiment of the first aspect or the second aspect, where the mᵢ is being the form mᵢ=2^{q}^{ᵢ}+1, 1≤i≤k, i is an integer and qᵢ is an integer. Note that qᵢ might not exist for particular mᵢ since not every modulo might be in form of 2^{q}^{ᵢ}+1. That is to say, for the m moduli of the moduli-set, qᵢ is exist just for the moduli which are being the form of 2^{q}^{ᵢ}+1. For example, if the moduli-set is {m₁, m₂}={5₁₀, 13₁₀}, the modulo m₁ is being the form of mᵢ=2^{q}^{ᵢ}+1, specifically, m₁=2^{q}^{₁}+1=2²+1 and q₁ is equal to 2. q₂ is not exist for the modulo m_{2.}

According to this embodiment, the use of the truncated modulo of the form mᵢ=2^{q}^{ᵢ}+1 and the use of the MSB of the said modulo mᵢ as the truncated bit lead to fewer RNS representations that needs to be recoded, hence the storage area, power consumption and latency for conversion are reduced. Compared with the use of the MSB of the truncated modulo as the truncated bit, this embodiment leads to fewer recoded RNS representations, and storage area, power consumption and latency for conversion are further reduced.

In an embodiment of the first aspect or the second aspect, where the mᵢ is the modulo that has the largest value of the k moduli.

According to this embodiment, the use of the MSB of the truncated modulo of the form mₖ=2^{q}^{ₖ}+1 which is the highest value modulo in a moduli-set leads to fewest possible recoded values in the bijection, and the advantages, such as storage area, power consumption, latency for conversion and so on, are maximized.

According to a third aspect, a chip (or a chip system) is provided. The chip has a function of implementing the method in the first aspect or in the second aspect, and any embodiments of the first aspect or the second aspect. The function may be implemented by using hardware structures. Alternatively, the chip or chip system includes an interface and a plurality of circuits.

According to a fourth aspect, a device is provided, including a chip or a chip system of the third aspect.

### BRIEF DESCRIPTION OF DRAWINGS

One or more embodiments are exemplarily described by corresponding accompanying drawings, and these exemplary illustrations and accompanying drawings constitute no limitation on the embodiments. Elements with the same reference numerals in the accompanying drawings are illustrated as similar elements, and the drawings are not limiting to scale, in which:

FIG. 1 is a schematic diagram of a method for converting first representations of values to second representations.

FIG. 2 is an example of a number of recoded RNS values in an 8-bit CRNS.

FIG. 3 shows an example of a trend graph of f for n=8.

FIG. 4 is a schematic diagram of a method for converting second representations of values to first representations.

FIG. 5 is a schematic diagram of an embodiment of converting from RNS to CRNS.

FIG. 6 is a schematic diagram of an embodiment of converting from RNS to CRNS.

FIG. 7 is a schematic diagram of an embodiment of converting from CRNS to RNS.

FIG. 8 is a schematic diagram of an embodiment of converting from CRNS to RNS.

FIG. 9 is a schematic diagram of an embodiment of converting from CRNS to RNS.

FIG. 10 is a schematic diagram of an embodiment of converting from CRNS to RNS.

FIG. 11 is a schematic block diagram of a chip or a chip system according to an embodiment of the present application.

### DESCRIPTION OF EMBODIMENTS

In order to understand features and technical contents of embodiments of the present disclosure in detail, implementations of the embodiments of the present disclosure will be described in detail below with reference to the accompanying drawings, and the attached drawings are only for reference and illustration purposes, and are not intended to limit the embodiments of the present disclosure. In the following technical descriptions, for ease of explanation, numerous details are set forth to provide a thorough understanding of the disclosed embodiments. One or more embodiments, however, may be practiced without these details. In other cases, well-known structures and apparatuses may be shown simplified in order to simplify the drawings.

Related technologies and concepts are introduced here firstly in order to better understand the technique solution proposed by the present application.

### 1. Residue Number System (RNS)

A RNS is defined by a set of k integers {m₁, m₂, . . . , mₖ} called a moduli-set. Any two integers in the moduli-set must be pairwise coprime, i.e. GCD (mᵢ, mⱼ)=1, i, j∈[1, k], i≠j. Let M be a product of all mᵢ: M=Πᵢ₌₁^{k}mᵢ, then an integer x in a range of [0, M−1] is uniquely represented in the RNS by a set of its residues x→{x₁, x₂, . . . , xₖ} under Euclidean division by the moduli-set; that is, rᵢ=x mod mᵢ and 0≤rᵢ<mᵢ for each i.

According to Chinese Remainder Theorem (CRT), x can be reconstructed from RNS as:

$${x = \vert {\sum }_{i = 1}^{k} \vert {r}_{i} {M}_{i}^{- 1} {\vert}_{{m}_{i}} {M}_{i} \vert}_{M} , {M}_{i} = \frac{M}{{m}_{i}} , {\vert {M}_{i} {M}_{i}^{- 1} \vert}_{{m}_{i}} = 1$$

The RNS has many advantages, such as independent (parallel) addition, subtraction and multiplication operations between corresponding remainders:

$$a + b = \{ {\vert {a}_{1} + {b}_{1} \vert}_{{m}_{1}} , {\vert {a}_{2} + {b}_{2} \vert}_{{m}_{2}} , … , {\vert {a}_{k} + {b}_{k} \vert}_{{m}_{k}} \}$$

$$a - b = \{ {\vert {a}_{1} - {b}_{1} \vert}_{{m}_{1}} , {\vert {a}_{2} - {b}_{2} \vert}_{{m}_{2}} , … , {\vert {a}_{k} - {b}_{k} \vert}_{{m}_{k}} \}$$

$$a * b = \{ {\vert {a}_{1} * {b}_{1} \vert}_{{m}_{1}} , {\vert {a}_{2} * {b}_{2} \vert}_{{m}_{2}} , … , {\vert {a}_{k} * {b}_{k} \vert}_{{m}_{k}}$$

Lack of carry propagation is a main interesting aspect of the RNS, because it reduces complexity, reduces power consumption and speed up the calculations compared with usual binary number system (BNS) representation.

The RNS also has limitations, for example, non-modular operations (comparison, scaling, etc.) are generally complex in RNS, transformation is slow between positioning and modular representations, and an overflow detection is difficult.

In the present application, it is important in the rest of the document to understand differences and to distinguish between a modulo mᵢ and a residual rᵢ under the modulo mᵢ, that is, rᵢ=|x|ₘ_{ᵢ}, where x is a BNS value being represented.

In addition, it is important to distinguish between “representation” and “value”. In BNS, a representation of a value x is a binary representation of x. The value x in the RNS and BNS is the same, but representations of the value x in the RNS and BNS are different.

For example, an integer 99₁₀ has a representation 1100011₂ in the BNS. In the RNS, the representation of the value x depends on the moduli-set of the RNS.

For example, for the RNS, in a given moduli-set m={3₁₀, 5₁₀, 7₁₀} of M=105₁₀, the value 99₁₀ gets a representation r={0, 4₁₀, 1₁₀} under the said moduli-set. For the said RNS, the binary form of residuals becomes {00₂, 100₂, 001₂}.

It can be shown from the above example, residuals r₁=0₁₀=00₂ occupies 2 bits, r₂=4₁₀=100₂ occupies 3 bits, and r₃=1₁₀=001₂ occupies 3 bits. In total 2₁₀+3₁₀+3₁₀=8₁₀ bits for the RNS representation, the residuals (that is, r₁, r₂ and r₃) are encoded into an 8-bit “RNS word” as shown below in Table 1.

TABLE 1

| RNS bit | 7 | 6 | 5 | 4 | 3 | 2 | 1 | 0 |
|---|---|---|---|---|---|---|---|---|
| Residual bit | r_{3.2} | r_{3.1} | r_{3.0} | r_{2.2} | r_{2.1} | r_{2.0} | r_{1.1} | r_{1.0} |
| Representation | 0 | 0 | 1 | 1 | 0 | 0 | 0 | 0 |
| of “99₁₀” | | | | | | | | |

In Table 1, “r_{3.2}” means “r3, bit 2”, “r_{2.1}” means “r2, bit 1”, and so on.

It can be shown according to Table 1, that an RNS representation of the value “99₁₀” under the said moduli-set {3₁₀, 5₁₀, 7₁₀} becomes “00110000₂” if we arrange residuals in such a way that a MSB of the RNS word is the MSB of the residual corresponding to the largest modulo mₖ (m₃ in this example), and the LSB of the RNS word is the LSB of the residual corresponding to the smallest modulo m₁, and residuals are ordered between mx and m₁.

Consider a BNS with n bits, the BNS has a dynamic range of 2ⁿ, and it can be shown that an RNS representation of an n-bit BNS always requires at least n+1 bits (combined bit-width of all residuals under the moduli-set) to represent a full dynamic range of 2ⁿ values.

It is known to all that it requires at least n bits to represent the 2ⁿ values [0; 2ⁿ−1].Therefore, the only way to represent 2ⁿ RNS values in n bits is M=2ⁿ. Because if M>2ⁿ, it requires more than n bits to represent M. If M=2ⁿ , then all factors of M will have to also be powers of 2, and if all factors of M are powers of two, then they all have 2 as a divisor themselves, so they are not co-prime. If they are not co-prime, then they are not a moduli set. If at least n bits are needed to represent an RNS representation and cannot be represented by n bits, then the RNS representation must have at least n+1 bits. For an 8-bit BNS value, the RNS representation will have at least 9 bits, for an 16-bit BNS value, the RNS representation will have at least 17 bits and so on.

This is inconvenient because an extra bit leads to additional data conversion between a main memory and an arithmetic logic unit (ALU), leading to bandwidth bottlenecks, reducing performance and increasing energy consumption at the same time. In addition, it requires more space to store RNS values than BNS values. For example, an 8-bit BNS value becomes a 9-bit RNS value, so it occupies 2 pcs 8-bit positions in the memory or register-bank. It is also inconvenient to convert BNS constants such as FIR-filter coefficients, and neural network weights every time they are used, because such conversion requires energy.

### 2. Huffman Compression

The Huffman compression relies on a non-uniform distribution of the used values, so that frequently used values are encoded with “small” codes, and infrequently used values are encoded with “larger” codes. The most infrequently used codes will be larger than the original values, because the codes are so called “prefix codes”.

Currently, there are some researches on the application of the Huffman compression in an RNS, such as Huffman compression of RNS residuals; Huffman encoding of an entire RNS value, and specifically, RNS values is treated as a dataset to be compressed by the Huffman encoding, and each of the used RNS residual values will be assigned a Huffman “code”.

However, RNS values have high entropy, and Huffman compression works very bad on RNS values. Some RNS values will be encoded as Huffman codes larger than the original RNS values, and not all encoded values will have the same size.

Example: A sentence “this is an example of a Huffman tree” contains 36 characters of 16 different values (including the character SPACE or “”).

Since there are only 16 different values, we can encode the characters using 4 bits.

TABLE 2

| | 4-bit | | Huffman |
|---|---|---|---|
| Char | code | Occurrence | code |
| SPACE | 0000 | 7 | 111 |
| A | 0001 | 4 | 010 |
| E | 0010 | 4 | 000 |
| F | 0011 | 3 | 1101 |
| H | 0100 | 2 | 1010 |
| I | 0101 | 2 | 1000 |
| M | 0110 | 2 | 0111 |
| N | 0111 | 2 | 0010 |
| S | 1000 | 2 | 1011 |
| T | 1001 | 2 | 0110 |
| L | 1010 | 1 | 11001 |
| O | 1011 | 1 | 00110 |
| P | 1100 | 1 | 10011 |
| R | 1101 | 1 | 11000 |
| U | 1110 | 1 | 00111 |
| X | 1111 | 1 | 10010 |

The above Table 2 shows characters, 4-bit codes, the number of occurrence in the sentence, and resulting Huffman codes. The most frequent letters (SPACE, A, E) all have 3-bit codes, while the most infrequent letters have 5-bit codes. The 5-bit codes are larger than the “straight” 4-bit codes, which could have been used to encode the data values directly. It can also be noted that 8 combinations (codes) can be formed from 3 bits, but only 3 combinations are used by the Huffman coding, 16 combinations can be formed from 4 bits, but only 7 combinations are used, and so on. This is due to the “prefix-code” requirement of the Huffman codes.

The above encoded sentence has a non-uniform distribution of values. The direct encoding as 4-bit values consumes 36*4=144 bits. The Huffman encoding consumes only 135 bits. Bit consumption is reduced by about 6%.

Consider a string of uniform distribution of values, where each of the 16 characters occur 2 times, for example, “AE FFXUXMNMHIST RORPLSTOPUNLHEIA”. There are 2*16=32 characters in total. Such a string needs 32*4=128 bits to be encoded directly, while the Huffman coding requires 134 bit. Bit consumption is increased by more than 5%.

It is commonly known that, Huffman coding requires the data to be non-uniformly distributed in order to be smaller than the source data. Huffman's agenda is to compress a natural language text. Most western languages have a non-uniform distribution of letters in a natural language, which makes Huffman compression feasible. General purpose data cannot be assumed to have such properties.

In general, mᵢ is far less than M, that is, mᵢ<<M, so a sequence of values of rᵢ will repeat itself

$$\frac{M}{{m}_{i}}$$

times through a range [0: M−1] of the RNS, where mᵢ is one of the moduli in the moduli-set of the RNS, and 0≤rᵢ<mᵢ. Values [0; mᵢ−1] will be close to uniformly represented in rᵢ, and values [mᵢ; 2^{p}^{ᵢ}−1] will have a frequency of zero, where pᵢ=[log₂(mᵢ−1)].

Even a non-uniform distribution of used values in the RNS may lead to a near-uniform distribution of values of residual r₂, 0≤rᵢ<mᵢ under mᵢ, where mᵢ<<M, for all mᵢ in the moduli of the RNS.

An example is given here.

Consider the moduli {m₁, m₂}={11₁₀, 13₁₀}, and M=m₁×m₂=143₁₀. Consider a dataset, BNS values [0; 10₁₀] occur 10₁₀ times each, BNS values [11₁₀; 100₁₀] occur 5₁₀ times each, and BNS values [101₁₀; 142₁₀] occur 1 time each. Such a dataset is highly non-uniform and the BNS would compress nicely with the Huffman compression. However, the occurrence of values of the residuals r₁ and r₂ are close to an ideal uniform distribution. In the case of r₁, values 0, 1 occur 58₁₀ times each, and all other values 54₁₀ each. In the case of r₂, values [0; 9₁₀] occur 48₁₀ times each, and other values 44₁₀, 39₁₀, and 39₁₀ times respectively. The residuals would not compress to a smaller result with the Huffman encoding.

It has been found that the Huffman compression of encoding the residuals is useless on RNS values. Furthermore, the Huffman compression does not hold if all values in the range [0; 2ⁿ−1] are used, because some of the codes would be larger than the RNS word. Dynamic Huffman compression will be very expensive (time, area, energy, etc.), so static Huffman encoding will have to be used. This implies that the statistic distribution of the values of the processed data have to be known at the time of design of the chip. This is not the case for general purpose computing. Therefore this approach is useless in general purpose computing.

According to the above states, a representation in RNS of an n-bit BNS value requires at least n+1 bit, this leads to memory bandwidth issues and increased storage usage for above reasons. Repeated conversion of values (for example, software constant) from BNS to RNS requires much energy and reduces computation speed.

In addition, storage of intermediate values from an RNS requires:
storage of 9-bit RNS format (which in praxis is 2×8 bits), which will lead to increased power consumption, memory bandwidth issues, and high use of intermediate storage area; and
reverse conversion from RNS to BNS, storage as 8 bit, and forward conversion from BNS to RNS when the intermediate values are read again, which will lead to increased power consumption, and potential delays.

Given that, the present application propose a compact residual number system (CRNS) and a method for converting representations of values between RNS and CRNS. The CRNS representation is an alternative representation based on any usual RNS representation. CRNS uses only n bits to represent all 2ⁿ values of n-bit BNS.

RNS values, representing a BNS value x, where 2ⁿ≤x<M, cannot be represented by CRNS, but these RNS values aren't used and aren't needed in the present application.

The mapping between RNS representations and CRNS representations proposed by the present application is efficient in terms of area and energy, and is more efficient than regular BNS-to-RNS forward conversion and (Chinese Remainder Theorem) CRT-based or (Mixed-Radix System) MRS-based reverse conversion.

The mapping is based on a bijection between RNS representations and CRNS representations. The present application also proposes ways to optimize the bijection, in order to reduce area, power consumption and latency for the conversion logic.

The present application can be applied in computational elements, such as central processing unit (CPU), arithmetic logic unit (ALU), graphical processing unit (GPU), neural network (NN) acceleration units. In general, the solution proposed by the present application can be used in any product to which RNS is applied.

It seems that “AI on the edge” is already a big trend and is getting bigger in the near future. Here, inference processing takes place in mobile devices such as cellular phones, cameras, wearable devices and embedded devices in general. This implies that use of RNS technology is beneficial, and so is the concept of compact RNS (CRNS). So CRNS of the present application is a number representation system, and it can use fewer bits to represent a BNS value compared to RNS. Specifically, CRNS can use n bits to represent values of an n-bit BNS, where the values are in a range of [0; 2ⁿ−1], and n is an integer.

The following describes the proposed solution of the present application in more details.

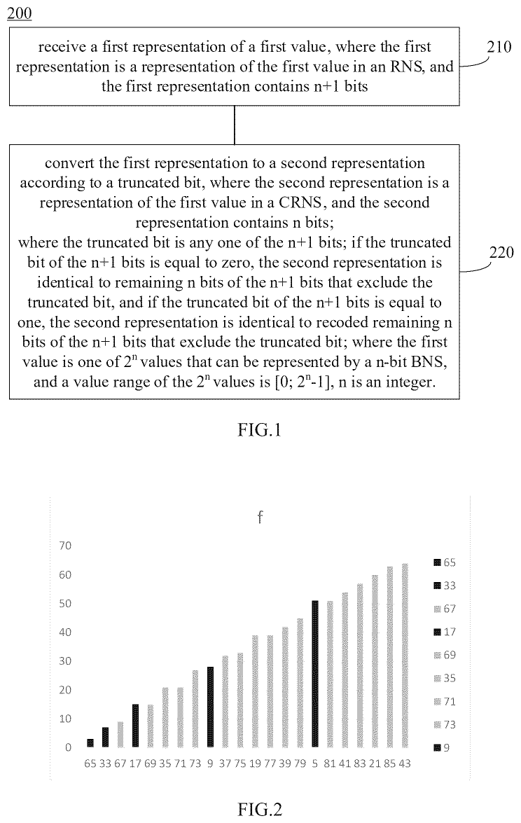

FIG. 1 is a schematic diagram of a method for converting first representations of values to second representations. A method (200) specifically includes the following steps:

Step 210: receive a first representation of a first value, where the first representation is a representation of the first value in an RNS, and the first representation contains n+1 bits.

Step 220: convert the first representation to a second representation according to a truncated bit, where the second representation is a representation of the first value in a CRNS, and the second representation contains n bits.

The truncated bit is predetermined, and it can be any one of the n+1 bits of the first representation.

The first value of is one of 2ⁿ values that can be represented by an n-bit BNS, and a value range of the 2ⁿ values is [0, 2ⁿ−1], n is an integer greater than or equal to 1.

In step 220, in the case that the truncated bit is equal to zero, the second representation is identical to remaining n bits of the first representation that exclude the truncated bit, and in the case that the truncated bit is equal to one, the second representation is identical to recoded remaining n bits of the first representation that exclude the truncated bit.

In other words, if the truncated bit is equal to zero, the second representation is a copy of remaining n bits of the first representation that exclude the truncated bit, and if the truncated bit is equal to one, the second representation is a copy of recoded remaining n bits of the first representation that exclude the truncated bit.

In the present application, the 2ⁿ values correspond to 2ⁿ first representations in the RNS, the 2ⁿ values correspond to 2ⁿ second representations in the CRNS, and the 2ⁿ first representation and the 2ⁿ second representation are in a bijection mapping relationship. In other words, any one of the 2ⁿ values corresponds to a first representation in the RNS and corresponds to a second representation in the CRNS.

Method 200 is a general description about performing mapping from RNS representation(s) to CRNS representation(s). It should be understood that, mapping from CRNS representation(s) to RNS representation(s) should also be covered by the present application. Embodiments about mapping between CRNS and RNS will be introduced specifically later in the document.

Alternatively, “first representation” also can be replaced with “RNS representation”, and “second representation” also can be replaced with “CRNS representation”, and it is not restricted in the present application.

It should be understood that, an n-bit BNS can represent 2ⁿ unique values x, where 0≤x<2ⁿ. Consider a (n+1)-bit RNS with a dynamic range M, where 2ⁿ≤M<2ⁿ⁺¹, the RNS can represent values x, where 0≤x<M, that is [0; M−1]. In the present application, a bijection which maps between the (n+1)-bit RNS representation and the n-bit CRNS representation is proposed. The bijection is a static bidirectional one-to-one mapping function. The bijection maps only 2ⁿ RNS values (including zero) which correspond to n-bit BNS values in the range 0≤x<2ⁿ. RNS values which correspond to BNS values larger than or equal to 2ⁿ are disregarded in the present application, and may produce any output results from the bijection mapping function, including but not limited to zero, a constant value, a random value, or any other value.

Table 3 shows an example of mapping from BNS to RNS, and mapping from RNS back to BNS.

TABLE 3

| A | B | | C | D | E | F |
|---|---|---|---|---|---|---|
| X | r₂ | r₁ | RNS | BNS | RNS | BNS |
| 0000 | 000 | 00 | 00000 | 0000 | 10000 | BNS = 18 |
| 0001 | 001 | 01 | 00001 | 0111 | 10001 | 0100 |
| 0010 | 010 | 10 | 00010 | 1110 | 10010 | 1011 |
| 0011 | 011 | 00 | 00011 | unused | 10011 | unused |
| 0100 | 100 | 01 | 00100 | 1111 | 10100 | 1100 |
| 0101 | 101 | 10 | 00101 | 0001 | 10101 | BNS = 19 |
| 0110 | 110 | 00 | 00110 | 1000 | 10110 | 0101 |
| 0111 | 000 | 01 | 00111 | unused | 10111 | unused |
| 1000 | 001 | 10 | 01000 | 1001 | 11000 | 0110 |
| 1001 | 010 | 00 | 01001 | BNS = 16 | 11001 | 1101 |
| 1010 | 011 | 01 | 01010 | 0010 | 11010 | BNS = 20 |
| 1011 | 100 | 10 | 01011 | unused | 11011 | unused |
| 1100 | 101 | 00 | 01100 | 0011 | 11100 | unused |
| 1101 | 110 | 01 | 01101 | 1010 | 11101 | unused |
| 1110 | 000 | 10 | 01110 | BNS = 17 | 11110 | unused |
| 1111 | 001 | 00 | 01111 | unused | 11111 | unused |

In table 3, the moduli-set is {3,7}, m₁=3, m₂=7, M=m₁×m₂=21, n=4, 2ⁿ=16. The columns A and B show a mapping from BNS to RNS, and some of the RNS values have MSB=1, as shown in bold in column B. The columns C to F show a mapping from RNS back to BNS. The values marked “unused” in columns D and F correspond to r₁=3 or r₂=7, r₁ is a residual under the modulo m₁, and r₂ is a residual under the modulo m₂. “Unused” values can't happen, because m₁=3 means 0≤r₁<3, and m₂=7 means 0≤r₂<7. The cases of r₂=7 represent binary combinations of the RNS-word, which are not valid RNS values, and hence also not valid BNS values. The present application is not concerned with these cases. The value marked “BNS=16” corresponds to BNS=16. This BNS value is outside the value range [0; 2ⁿ−1]. The values marked BNS=17, 18, 19 or 20 are similar. These RNS values are not used, because they represent a BNS value which can not be represented in the n-bit BNS.

As stated above, the bijection maps representations of 2ⁿ RNS values which corresponds to an n-bit BNS value in the range 0≤x<2ⁿ to 2ⁿ representations in a CRNS respectively.

The n-bit second representation is created from remaining n bits by truncating a certain RNS-bit of the RNS word, that is, the n+1 bits of the first representation, and the “truncated bit” is called the bit RNSⱼ in the present application. In other words, a certain RNS bit is chosen from the first representation as the “truncated bit”. When converting a first representation in RNS of any one of the 2ⁿ values to a second representation in CRNS, if the bit RNSⱼ (that is, the truncated bit) is equal to “0”, the second representation is a copy of remaining n bits of the first representation that exclude the bit RNSⱼ, that is, the n-bit second representation is identical to the remaining n bit of the first representation that excludes the bit RNSⱼ, and if the bit RNSⱼ is equal to “1”, the second representation is obtained by performing recoding on the remaining n bits of the RNS word excluding the bit RNSⱼ. Specifically, the remaining n bits of the RNS word excluding the bit RNSⱼ are recoded to a different, unused, CRNS value, that is, a CRNS value which is not occupied by the RNS values with the bit RNSⱼ=0.

It can be shown that the number of RNS values which have RNSⱼ=1 correspond exactly to the number of “unused” CRNS values. The “used” CRNS values correspond to the RNS values which have RNSⱼ=0.

It has been proved by the present application, an n-bit BNS with 2ⁿ values [0; 2ⁿ−1] leads to a (n+1)-bit RNS. If ho values of the 2ⁿ values have RNSⱼ=0, then h₁=2ⁿ−h₀ values have RNSⱼ=1. Then n-bit CRNS representation also has 2ⁿ possible values. When c₀ CRNS values are mapped directly from RNS, then c₀=h₀. Then c₁=2ⁿ−c₀ values are left to be used for remapped RNS values which have RNSⱼ=1. Since c₀=h₀⇒c₁=h₁, then the number of “unused” positions in the CRNS range will always correspond to the number of RNS values with RNSⱼ=1. “Remapped” in the present application equals “recoded”, so “remapped values” also means “recoded values”.

An n-bit BNS can represent 2ⁿ values, the 2ⁿ values correspond to 2ⁿ first representations in the RNS and correspond to 2ⁿ second representations in the CRNS, and the 2ⁿ first representations and the 2ⁿ second representations are in a bijection mapping relationship.

The 2ⁿ first representations include f first representations of a first type and (2ⁿ−f) first representations of a second type, the truncated bit of the first representation of the first type is equal to one, and the truncated bit of the first representation of the second type is equal to zero.

If we consider a sequence of m; integers [0; mᵢ−1], then the number of elements having MSB=1 is h₁, and h₁ can be calculated like h₁=mᵢ−2^{p}^{ᵢ}⁻¹, pᵢ=[log₂(mᵢ−1)]. This sequence of numbers repeat

$$\frac{{2}^{n}}{{m}_{i}}$$

times though a value range [0, 2ⁿ−1]. The number

$$\frac{{2}^{n}}{{m}_{i}}$$

will not be an integer unless mᵢ is a power of 2. Therefore, there can be some values close to M, which also have MSB=1, but not the full amount of h₁ above.

Let the value f be the number of values to be remapped, i.e., the number of RNS values, where RNSⱼ=1. A general formula for f for any mᵢ is shown below. It is remarkable that f does not depend on neither the other modulo nor M, but only on n and mᵢ, where n is the number of bit of a representation in the CRNS and BNS, mᵢ is the modulo to be truncated, and pᵢ is the number of bit required to represent rᵢ under mᵢ, (i.e. pᵢ=[log₂(mᵢ−1)]).

$$f = \{ \begin{matrix}⌊ \frac{{2}^{n}}{{m}_{i}} ⌋ ( {m}_{i} - {2}^{{p}_{i} - 1} ) , & if {\vert {2}^{n} \vert}_{{m}_{i}} \leq {2}^{{p}_{i} - 1} \\ ⌊ \frac{{2}^{n}}{{m}_{i}} ⌋ ( {m}_{i} - {2}^{{p}_{i} - 1} ) + {\vert {2}^{n} \vert}_{{m}_{i}} - {2}^{{p}_{i} - 1} , & if {\vert {2}^{n} \vert}_{{m}_{i}} > {2}^{{p}_{i} - 1}\end{matrix}$$

Example: let the moduli-set m={m₁, m₂}={5₁₀, 13₁₀}, M=m₁×m₂=65₁₀, n=6, p₁=3, p₂=4, and the 7-bit moduli-set m has 65 values and can represent values in a value range of [0; 63] of a 6-bit BNS.

Let's look at the values of x, r₁, r₂ near the end of the useful range [0; 2ⁿ−1]=[0; 63].

TABLE 4

| x | r₁ = \|x\|₅ | r₂ = \|x\|₁₃ |
|---|---|---|
| 55₁₀ | 000 | 0011 |
| 56₁₀ | 001 | 0100 |
| 57₁₀ | 010 | 0101 |
| 58₁₀ | 011 | 0110 |
| 59₁₀ | 100 | 0111 |
| 60₁₀ | 000 | 1000 |
| 61₁₀ | 001 | 1001 |
| 62₁₀ | 010 | 1010 |
| 63₁₀ | 011 | 1011 |
| 2ⁿ = 64₁₀ | 100 | 1100 |
| M = 65₁₀ | 000 | 0000 |

As an example, we will first assume that m₁=5 is the truncated modulo, also known as r₁ is the truncated residual.

The final repetition of the sequence corresponding to m₁ (we call it “m₁ sequence” in the following text) has only 4 of the 5 values, and all of these values have MSB=0. |2ⁿ|m₁≤2^{p}^{ᵢ}⁻¹⇒|64|₅≤2³⁻¹⇒4≤4, true. Therefore, we are in the upper part of the equation of f above.

$$⌊ \frac{{2}^{n}}{{m}_{1}} ⌋$$

is the number of complete repetitions of the m₁ sequence.

$$⌊ \frac{{2}^{n}}{{m}_{1}} ⌋ = ⌊ \frac{{2}^{6}}{5} ⌋ = ⌊ 12.8 ⌋ = 12 .$$

mᵢ−2^{p}^{ᵢ}⁻¹ is the number of occurrences of MSB=1 in each repetition. mᵢ−2^{p}^{ᵢ}⁻¹=m₁−2³⁻¹=5−4=1. The final repetition of the mᵢ sequence does not lead to any occurrence of MSB=1 in r₁, so f=12×1=12.

Now consider m₂ is the truncated modulo. The last repetition of the sequence corresponding to m₂ (we call it “m₂ sequence” in the following text) has only 12 of the 13 values present, and 4 of those have MSB=1.

$$⌊ \frac{{2}^{n}}{{m}_{2}} ⌋$$

is the number of complete repetitions of the m₂ sequence.

$$⌊ \frac{{2}^{n}}{{m}_{2}} ⌋ = ⌊ \frac{{2}^{6}}{13} ⌋ = ⌊ 4.9231 ⌋ = 4.$$

m₂−2^{p}^{₂}⁻¹=m₂−2⁴⁻¹=13−8=5. Therefore, there are 4×5=20 occurrences of MSB=1 in the first 4 repetitions of the m₂ sequence. The final repetition of the m₂ sequence has the first |2ⁿ|m₂=|2⁶|m₂=|64|₁₃=12 of the 13 values in the m₂ sequence before 2ⁿ=64 is reached.

It requires p₂ (p₂=4) bits to represent r₂, so the first 8 (2^{p}^{₂}⁻¹=2⁴⁻¹=8) of these 12 values have MSB=0. The last 4 (|2ⁿ|m₂−2^{p}^{₂}⁻¹=|64|₁₃−2⁴⁻¹=12−8=4) values of the m₂ sequence have MSB=1, so f=4×5+4=24.

In addition, there are two special cases of f:
For a modulo mᵢ being the form mᵢ=2^{q}^{ᵢ}+1:

$$f = ⌊ \frac{{2}^{n}}{{m}_{i}} ⌋$$

. . . (minimum value of f as fraction of number of BNS values);
For a modulo mᵢ being the form mᵢ=2^{q}^{ᵢ}:

$$f = \frac{{2}^{n}}{2} = {2}^{n - 1}$$

. . . (maximum value of f as fraction of number of BNS values).

The 23 smallest values of f for n=8 and mᵢ≤128 are shown in graph of FIG. 2. Moduli of the form mᵢ=2^{q}^{ᵢ}+1 are marked in black in FIG. 2. FIG. 2 shows an example of a number of recoded RNS values, f, in an 8-bit CRNS with corresponding 9-bit RNS and 9-bit BNS.

It can be shown according to FIG. 2, even though 9 is a fairly small number and a modulo of 9 will repeat many times

$$( specifically , ⌊ \frac{{2}^{8}}{9} ⌋ = 28 times )$$

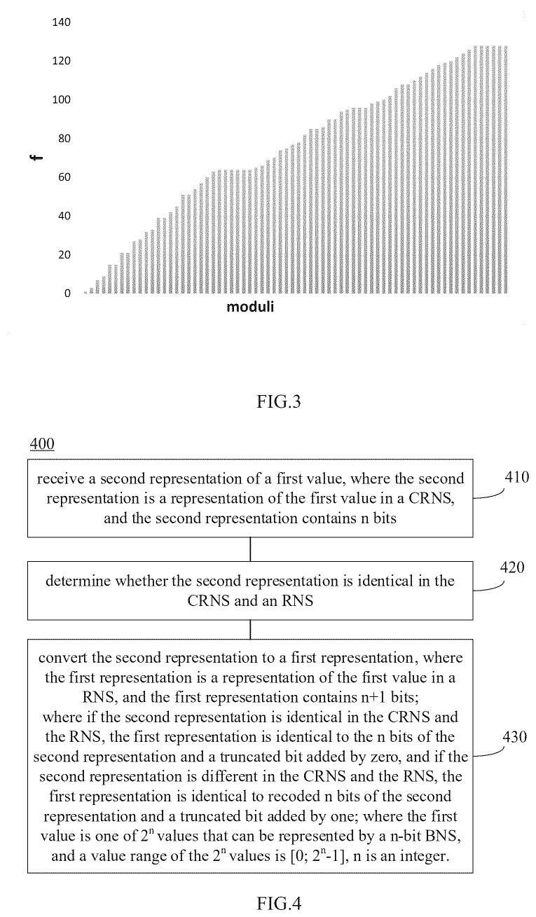

through the 8-bit value range of [0; 255]. There are only 5 values of moduli which result in smaller f and are not of the form mᵢ=2^{q}^{ᵢ}+1. FIG. 3 shows an example of a trend graph of f for n=8. f continues to grow steadily towards

$$f = \frac{{2}^{8}}{2} = 128 .$$

All moduli of the form mᵢ=2^{q}^{ᵢ} have

$$f = \frac{{2}^{8}}{2} = 128 .$$

Note that FIG. 3 is just for illustration of trend of f, and the value of f is not shown out.

Table 5 is an example of the method for converting representations of values from RNS to CRNS.

TABLE 5

| A | B | C | D | E | F | |
|---|---|---|---|---|---|---|
| X | r₂ | r₁ | r₂ | r₁ | r_{2.1} r_{2.0} r_{1.1} r_{1.0} | G |
| 0 | 0 | 0 | 000 | 00 | 0000 | |
| 1 | 1 | 1 | 001 | 01 | 0101 | |
| 2 | 2 | 2 | 010 | 10 | 1010 | |
| 3 | 3 | 0 | 011 | 00 | 1100 | |
| 4 | 4 | 1 | 100 | 01 | | 0011 |
| 5 | 5 | 2 | 101 | 10 | | 0111 |
| 6 | 6 | 0 | 110 | 00 | | 1001 |
| 7 | 0 | 1 | 000 | 01 | 0001 | |
| 8 | 1 | 2 | 001 | 10 | 0110 | |
| 9 | 2 | 0 | 010 | 00 | 1000 | |
| 10 | 3 | 1 | 011 | 01 | 1101 | |
| 11 | 4 | 2 | 100 | 10 | | 1011 |
| 12 | 5 | 0 | 101 | 00 | | 1110 |
| 13 | 6 | 1 | 110 | 01 | | 1111 |
| 14 | 0 | 2 | 000 | 10 | 0010 | |
| 15 | 1 | 0 | 001 | 00 | 0100 | |

In table 5, m={3,7}, m₁=3, m₂=7, M=m₁×m₂=21, n=4, 2ⁿ=16. For an n-bit BNS, where n=4, only values belong to a values range [0; 15] are needed.

In table 5, as an example, the truncated bit is the MSB of r₂. According to the method for converting an RNS representation to a CRNS representation proposed by the present application, if the truncated bit of a first representation is equal to zero, such as first representations of the values 0, 1, 2, 3, 7, 8, 9, and 10, the second representation is identical to remaining n bits of corresponding first representation that exclude the truncated bit, and the truncated bit of a first representation is equal to one, such as first representations of the values 4, 5, 6, 11, 12 and 13, the second representation is identical to remaining n bits of corresponding to first representation that exclude the truncated bit. For example, the first representation of 4 is “10001” which contain 5 bits, and the remaining 4 ((n+1)−1=5−1=n) bits of the first representation excluding the truncated bit is “0001”, and the second representation of 4 is identical to recoded remaining 4 bits, specifically, the remaining 4 bits are recoded as “0011”, and the second representation is identical to the recoded word, i.e., “0011”.

In the above embodiments, the truncated bit is selected from a residual, and we can call this residual the truncated residual. The truncated residual relates to a modulo, and we will call this modulo the truncated modulo, even if it is actually the residual, which is truncated. The n+1 bits of the first representation includes k parts, which are the k residuals, and the k residuals are in one-to-one correspondence with the k moduli in the moduli-set. Alternatively, the k residuals are arranged in one of the following orders:
in an ascending order according to corresponding values of the k moduli;
in an descending order according to corresponding values of the k moduli; or in a random order.

For an example, in table 5, a first representation (i.e. RNS value) includes 5 bits, and the 5 bits include two parts. The said two parts are the two residuals r₁ and r₂, corresponding to the two moduli m₁ and m₂, respectively. The two parts are arranged in a descending order according to the values of the two moduli, specifically, in an order of r₂r₁. The truncated bit can be any of the bits contained in r₂ or r₁, where r₂ contains 3 bits, and r₁ contains 2 bits. As another example, the two parts are arranged in an ascending order like r₁r₂ according to values of the two moduli. As an example, if the moduli-set includes k moduli and k is larger than two, the k parts of the first representation can be arranged in a random order. For example, the moduli-set is {m₁, m₂, m₃}={3₁₀, 5₁₀, 7₁₀}, where k=3, three parts of the first representation can be arranged as the order like r₁r₂r₃, r₃r₂r₁, r₂r₁r₃ or r₂r₃r₁ and so on, and it is not listed here one by one.

Alternatively, as an example, the n+1 bits of the first representation also can be arranged in a random order, and not be arranged to the k parts. That is to say, the n+1 bits of the k parts are interleaved, and the truncated bit is one of the interleaved n+1 bits.

Alternatively, the bijection mapping relationship between the 2ⁿ first representations and the 2ⁿ second representations is adjustable.

Note that it is possible to permutate the output of the RNS-to-CRNS remapping function. That is to say, the actual CRNS values do not matter. The only thing which matters, is that the mapping is a bijection. The bijection property is a necessary and sufficient condition to ensure that the CRNS values can be mapped back to RNS values again. In order to do logic optimization, as an example, we will only permutate the RNS values which are re-mapped (or “re-coded”), and we will not permutate the RNS values which are “copied”. The 2ⁿ first representations include f first representations of a first type and (2ⁿ−f) first representations of a second type. The truncated bit of the first representation of the first type is equal to zero, and the truncated bit of the first representation of the second type is equal to one. As an embodiment, it is possible to permutate the bijection mapping relationship between the f first representations of the first type and corresponding f second representations. Take Table 5 as an example, the number of the first representation of the first type is six, and the six first representations of the first type correspond to values 4, 5, 6, 11, 12 and 13. The bijection mapping relationship shown in Table 5 is just an example, and the bijection mapping relationship of the six first representations of the first type and corresponding six second representation can be adjusted. In other words, the RNS values which have RNSⱼ=0 in the RNS representation will not be permutated. The fact that the RNS values where RNSⱼ=1 are re-recoded and the RNS values where RNSⱼ=0 are not, helps to clearly distinguish the present application from anything to do with the Huffman encoding.

It should be noted that, in the Huffman encoding, Huffman code will in general be different from the value it represents, any occurrence of the Huffman code being equal to the value it represents will be coincidental.

In other words, this embodiment is the permutation of outputs of a remapping function in such a way that any CRNS bit such as CRNSⱼ becomes a function of any one RNS bit such as RNSₜ in logic expressions: CRNSⱼ=RNSₜ or CRNSⱼ=not (RNSₜ) for any combination of j and t, and we will call this property “bit alignment”.

Alternatively, this embodiment also covers a situation where several combinations of RNS-bit and CRNS-bit are “bit alignment” at the same time, through a permutation of the remapped values.

According to embodiments stated above, n-bit CRNS representations are created by truncating the bit RNSⱼ of an RNS word. Alternatively, as an embodiment, the truncated bit is the MSB of an RNS word. Use of the MSB leads to fewer RNS values with RNSⱼ=1, so less logic in a recoding function.

Let RNSⱼ be the MSB of a modulo, mᵢ, in the moduli-set. This modulo mᵢ needs pᵢ bits for its representation of the residual rᵢ, where pᵢ=[log₂(mᵢ−1)], 0≤rᵢ<mᵢ. Of the mᵢ possible values of rᵢ, h₀=2^{p}^{ᵢ}⁻¹ values have MSB(rᵢ)=0, h₁=mᵢ−h₀ values have MSB(rᵢ)=1. If mᵢ=2^{p}^{ᵢ}, then h₁=h₀=2^{p}^{ᵢ}⁻¹. In all other circumstances, h₁<h₀. Therefore, there can never be more values of rᵢ where MSB(rᵢ)=1 than MSB(rᵢ)=0. If the modulo mᵢ is not of the form mᵢ=2^{p}^{ᵢ}, then there will be fewer values of rᵢ where MSB(rᵢ)=1 than where MSB(rᵢ)=0.

Alternatively, as a further example, the truncated bit is the MSB of a modulo, and the modulo is being of the form mᵢ=2^{p}^{ᵢ}+1. It can be shown that use of the MSB of a modulo of the form mᵢ=2^{p}^{ᵢ}+1 leads to the fewest possible recoded RNS values, specifically, only one RNS value, within the sequence of mᵢ residuals. Other forms of a modulo will have more than one recoded value per sequence of mᵢ residuals.

It has been proved by the present application, if the modulo mᵢ is of the form mᵢ=2^{q}^{ᵢ}+1, the values of the residual rᵢ under mᵢ will be in a range 0≤rᵢ<mᵢ, then the highest value of rᵢ is mᵢ−1=2^{q}^{ᵢ}.

Therefore, only the value rᵢ=mᵢ−1=2^{q}^{ᵢ} will have MSB(rᵢ)=1. Any other form of modulo will lead to a higher fraction of values of having MSB(rᵢ)=1.

Alternatively, as an example, the truncated bit of an RNS word is the MSB of a residual rₖ corresponding to a modulo mₖ of the form mₖ=2^{q}^{ₖ}+1, where the modulo mₖ is the highest value in the moduli-set.

It has been proved by the present application, if the modulo mᵢ which has its MSB truncated is of the form mᵢ=2^{q}^{ᵢ}+1, then the number of values in the value range [0; 2ⁿ−1] which will have to be recoded is

$$f = \frac{{2}^{n}}{{m}_{i}} .$$

Since f and mᵢ are inversely proportional, it is clear that the larger mᵢ is, then smaller the f will be. If mᵢ is the highest value modulo in the moduli-set, then no other modulo in the moduli-set will lead to a smaller value of f. Therefore, the use of the MSB of a residual corresponding to a modulo of the form mₖ=2^{q}^{ₖ}+1 which has the highest value in the moduli-set leads to the fewest possible recoded values in the bijection, compared with other choices of the truncated bit, for a given moduli-set.

Note that there may exist another modulo in another moduli-set than the said moduli-set, which leads to smaller value of f.

The method 400 for converting second representations to first representations are described below.

FIG. 4 is a schematic diagram of a method for converting the second representations of values to the first representations. A method (400) specifically includes the following steps:

Step 410: receive a second representation of a first value, where the second representation is a representation of the first value in a CRNS, and the second representation contains n bits.

Step 420: determine whether the second representation is identical in the CRNS and an RNS.

Step 430: convert the second representation to a first representation, where the first representation is a representation of the first value in the RNS, and the first representation contains n+1 bits;
where if the second representation is identical in the CRNS and the RNS, the first representation is identical to the n bits of the second representation and a truncated bit added by zero, and if the second representation is different in the CRNS and the RNS, the first representation is identical to recoded n bits of the second representation and the truncated bit added by one. In other words, the first representation is identical to a combination of the n bits of the second representation and a truncated bit added by zero in the case that the second representation is identical in the CRNS and the RNS, or the first representation is identical to a combination of recoded n bits of the second representation and the truncated bit added by one in the case that the second representation is different in the CRNS and the RNS. The truncated bit in method 400 is predetermined.

In step 420, if the second representation belongs to the f second representations corresponding to the f first representations of the first type, then the second representation is different in the CRNS and the RNS, and if the second representation does not belong to the f second representations corresponding to the f first representations, then the second representation is identical in the CRNS and the RNS, where the f second representations are predetermined. For f second representations corresponding to the f first representations of the first type, reference can be made to the embodiments of the method 200, and it is not repeated here.

The first value is one of 2ⁿ values, the 2ⁿ values can be represented by an n-bit BNS, and a value range of the 2ⁿ values is [0; 2ⁿ−1], n is an integer.

Note that converting CRNS representations to RNS representations is an inverse operation of converting RNS representations to CRNS representations. The truncated bit can be any one of the n+1 bits of the first representations in method 200, so the truncated bit in method 400 can be added in any position of the n bits of the second representations, such as a position before the n bits, after the n bits, or between any two adjacent bits of the n bits. For the truncated bit in method 400, reference can be made to explanations of the truncated bit in method 200, and it is not repeated here.

Some detailed implementations are given below about how to converting (n+1)-bit RNS representations to n-bit CRNS representations.

Alternatively, as an example, a 2:1 multiplexer and a logic function is used to implement the bijection from RNS to CRNS.

FIG. 5 is a schematic diagram of an embodiment of converting from RNS to CRNS. The notation “n: 0” means “bit n to bit 0”, and the notation “n−1:0” means “bit n−1 to bit 0”. The notation “n:0\j” means “bit n to 0 except bit j”, and the notation “\” is borrowed from math “set-theory”, where “\” is the exclusion operator. These notations are applicable in the following embodiments, and will not be repeated.

As shown in FIG. 5, in case of the bit RNSⱼ is equal to “0”, the RNS representation is mapped directly to a CRNS representation, and the CRNS representation is identical to the remaining n bit of the RNS representation that excludes the bit RNSⱼ. In case of the bit RNSⱼ is equals to “1”, the remaining n bits of the RNS representation that exclude the bit RNSⱼ is recoded to a CRNS representation which is not occupied by the RNS representations with RNSⱼ=0. In this embodiment, whether an RNS representation should be recoded depends on the bit RNSⱼ of the RNS representation is equals to “0” or “1”.

Alternatively, as an example, the truncated bit (that is, the bit RNSⱼ) is the MSB of a modulo mᵢ of the form mᵢ=2^{q}^{ᵢ}+1.

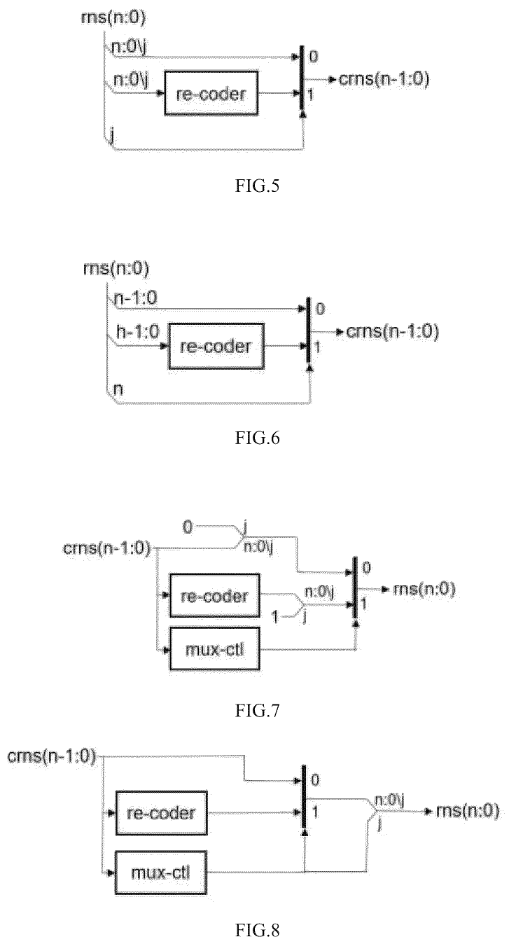

FIG. 6 is a schematic diagram of an embodiment of converting from RNS to CRNS. In this embodiment, the number of inputs to a re-coder function can be reduced by the number of bits, pᵢ=qᵢ+1, in the truncated modulo mᵢ, so h=n−pᵢ in the FIG. 6. We know that mᵢ=2^{q}^{ᵢ}+1 and the residual rᵢ under mᵢ belongs to the range 0≤rᵢ<mᵢ, where qᵢ is an integer corresponding to mᵢ. Therefore, the only occurrence of MSB(rᵢ)=1 is when rᵢ=mᵢ−1=2^{q}^{ᵢ}. Since a value of rᵢ is constant when the re-coder function is used, the value of rᵢ in the inputs of the re-coder function can be disregarded.

The number of inputs to the re-coder function is reduced by pᵢ, also known as the number of bits of the residual rᵢ, so complexity is reduced. Optional, as an example, the inputs to the re-coder function is bit 0 to bit h−1, that is, (h−1:0) as shown in FIG. 6. All other forms of truncated moduli lead to only one bit being removed from the inputs, namely the bit RNSⱼ. In a moduli-set with k moduli, mₖ is the modulo which has the largest value in the moduli-set. If the truncated modulo is mₖ, then advantages are maximized.

As shown in FIG. 6, it is assumed that the truncated bit is the MSB of the modulo which has the largest value in the moduli-set, and the modulo which has the largest value has form of mₖ=2^{q}^{ₖ}+1, where qₖ is an integer corresponding to mₖ. The modulo which has the largest value will be expressed as “the largest value modulo” instead in some embodiments for brevity. The truncated bit, that is the RNSⱼ, in this embodiment shown in FIG. 6 is “bit n”. The remaining n bits of the (n+1)-bit RNS representation, excluding bit n, are bit n−1 to bit 0 specifically. In case of the bit n (an example of the bit RNSⱼ) is equals to “0”, the (n+1)-bit RNS representation will be mapped directly to an n-bit CRNS representation, and the n-bit CRNS representation is identical to the remaining n bits of the (n+1)-bit RNS representation that exclude bit n. In case of the bit n of the (n+1)-bit RNS representation is equals to “1”, the remaining n bits of the (n+1)-bit RNS representation that exclude the truncated bit needs to be recoded. The recoded n bits is not occupied by the CRNS representations which corresponding to RNS representations with bit n is equals to “0”.

Note that no modulo will have more bits in its representation than the modulo which has the highest value, so if the modulo which has the highest value is the form mₖ=2^{q}^{ₖ}+1, the advantages are maximized.

There may be other moduli mₜ which have the same number of bits as the modulo mₖ, but no modulo will have more bits than the largest value modulo. In addition, any other moduli of the form mₜ=2^{q}^{ₜ}+1 will have to have fewer bits than the largest modulo, because qₜ will have to be smaller than qₖ, qₜ<qₖ=>pₜ<pₖ.

This embodiment shown in FIG. 6 is a continuation of a foregoing embodiment, and the foregoing embodiment is the embodiment which use a modulo of the form mᵢ=2^{q}^{ᵢ}+1 in order to reduce the number of recoded RNS values. The point of this embodiment is to use a 2:1 multiplexer and to reduce the number of inputs to the re-coder function at the same time as the number of recoded values are reduced in the foregoing embodiment. This embodiment shown in FIG. 6 is an improvement of the embodiment shown in FIG. 5 in the situation where the truncated modulo has a special form, that is mᵢ=2^{q}^{ᵢ}+1.

Some detailed implementations are given below about how to converting n-bit CRNS representations back to (n+1)-bit RNS representations.

FIG. 7 is a schematic diagram of an embodiment of converting from CRNS to RNS. A CRNS-to-RNS conversion uses a 2:1 multiplexer and a logic function (here called “mux-ctrl”) to implement the bijection from CRNS to RNS.

As shown in FIG. 7, a “mux-ctrl” function identifies all recoded CRNS representations, and determine whether an input CRNS representation is identical in the CRNS and the RNS or not. The 2:1 multiplexer passes CRNS representations which are identical in the CRNS and the RNS. A re-coder function recodes the CRNS representations which are different in the CRNS and the RNS. When the multiplexer passes CRNS representations directly to RNS, the output of the re-coder function is disregarded. This allows for optimization of implementation of a logic of the re-coder function. We know that, if the bit RNSⱼ=0, the CRNS representations are passed unchanged, and if the bit RNSⱼ=1, the re-coder function is used. Therefore, the bit RNSⱼ can be added as a constant before the multiplexer, as shown in FIG. 7. Specifically, the above 2ⁿ values of an n-bit BNS correspond 2ⁿ RNS representations and 2ⁿ CRNS representations, respectively. The 2ⁿ CRNS representations include f CRNS representations, and the f CRNS representations correspond f RNS representations of the first type in RNS. Each of the f CRNS representations is identical in the CRNS and the RNS. The f CRNS representations are predetermined and are known to the hardware, so the hardware can be designed to identify whether a CRNS representation is identical in the CRNS and the RNS or not.

Alternatively, as an example, the truncated bit, that is, the bit RNSⱼ, can also be inserted after the multiplexer, by using the output of the “mux-ctrl” function directly, as shown in FIG. 8. FIG. 8 is a schematic diagram of an embodiment of converting from CRNS to RNS.

Alternatively, as another example, the present application also cover the case where the output of the “mux-ctrl” function is inverted, and the inverted value of the output is merged directly into the RNS value as the bit RNSⱼ after the multiplexer, as shown in FIG. 9. FIG. 9 is a schematic diagram of an embodiment of converting from CRNS to RNS. Note that the multiplexer inputs are swapped in FIG. 9, because a polarity of a control signal for the multiplexer is changed.

Alternatively, in an embodiment stated above, the truncated bit, that is the RNSⱼ, is the MSB of a modulo of the form mᵢ=2^{q}^{ᵢ}+1, then a width of the output of the re-coder function can be reduced by pᵢ=qᵢ+1 bit. In the case that the truncated bit is the MSB of the modulo of the form mᵢ=2^{q}^{ᵢ}+1, then the width of the output of the re-coder function can be reduced by pᵢ=qᵢ+1, then the number of outputs of a logic function is reduced by pᵢ/n×100%, then the amount of gates and the occupied area are reduced by approximately the same relative amount, though not every output has the same logic function and complexity.

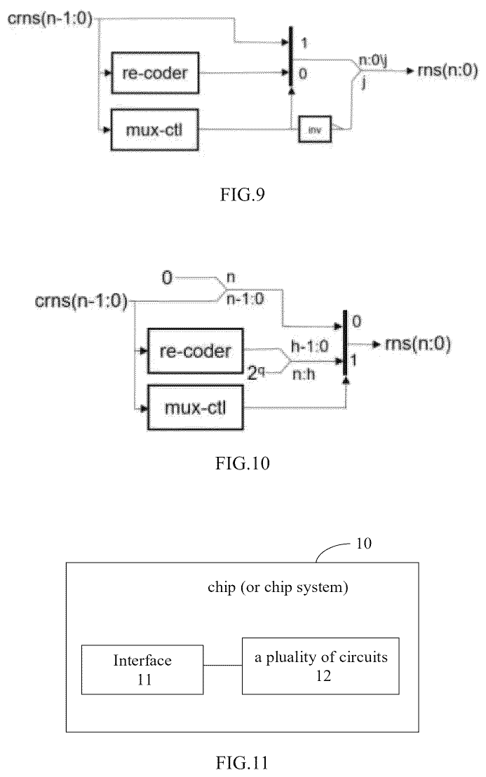

FIG. 10 is a schematic diagram of an embodiment of converting from CRNS to RNS. It shows that, p=n−h+1 bits of the truncated modulo mᵢ are located as the most significant bits, that is, bits [n: h] of an RNS word. The bit RNSⱼ then becomes RNSₙ, actually, j=n. The present application should cover the case that the truncated residual rᵢ corresponding to the truncated modulo mᵢ can be anywhere in the RNS word, not only in the most significant bits. FIG. 10 will be overly complicated, if it is generalized in this way, so FIG. 10 is only an example.

FIG. 11 is a schematic block diagram of a chip or a chip system 10 of the present application.

As shown in FIG. 11, the chip (or the chip system) may include an interface 11 and a plurality of circuits 12. Alternatively, the interface 11 is configured to receive RNS representations of values, and transmit the RNS representations to the plurality of circuits 12. The plurality of circuits 12 perform the method 200, to convert the RNS representations to CRNS representations. Alternatively, the interface 11 is used to receive CRNS representations of values, and transmit the CRNS representations to the plurality of circuits 12. The plurality of circuits 12 perform the method 400, to convert the CRNS representations to RNS representations.

Alternatively, the interface 11 includes an input interface and an output interface, where the input interface is configured to receive RNS representations or second representations, and the output interface is configured to output the converting result of the plurality of circuits 12. As an embodiment, the interface 11 is an interface circuit.

As an embodiment, the function of the chip is implemented by hardware, such as the plurality of circuits 12, and the hardware includes one or more corresponding structures, such as multiplexers, controllers, re-coders and logical gates and so on.

In the several embodiments provided in this application, it should be understood that the disclosed system and method may be implemented in other manners. For example, the described apparatus embodiment is merely an example. For example, the unit division is merely logical function division and may be other division in actual implementation. For example, a plurality of units or components may be combined or integrated into another system, or some features may be ignored or not performed. In addition, the displayed or discussed mutual couplings or direct couplings or communication connections may be implemented through some interfaces. The indirect couplings or communication connections between the apparatuses or units may be implemented in electronic, mechanical, or other forms.

The units described as separate parts may be or may not be physically separate, and parts displayed as units may be or may not be physical units, may be located in one position, or may be distributed on a plurality of network units. Some or all of the units may be selected based on actual requirements to achieve the objectives of the solutions of the embodiments.

In addition, functional units in the embodiments of this application may be integrated into one processing unit, or each of the units may exist alone physically, or two or more units are integrated into one unit.

The foregoing descriptions are merely specific implementations of this application, but are not intended to limit the protection scope of this application. Any variation or replacement readily figured out by a person skilled in the art within the technical scope disclosed in this application shall fall within the protection scope of this application. Therefore, the protection scope of this application shall be subject to the protection scope of the claims.

What is claimed is:

1. A method for converting presentations of values in different systems, performed by a chip, comprising:
receiving a first representation of a first value, wherein the first representation is a representation of the first value in a residual number system (RNS), and the first representation contains n+1 bits;
converting the first representation to a second representation according to a truncated bit, wherein the second representation is a representation of the first value in a compact residual number system (CRNS), and the second representation contains n bits;
wherein the truncated bit is any one of the n+1 bits, and if the truncated bit of the n+1 bits is equal to zero, the second representation is identical to remaining n bits of the n+1 bits contained in the first representation that exclude the truncated bit, and if the truncated bit of the n+1 bits is equal to one, the second representation is identical to recoded remaining n bits of the n+1 bits contained in the first representation that exclude the truncated bit;
wherein the first value is one of 2ⁿ values, the 2ⁿ values can be represented by an n-bit binary number system (BNS), and a value range of the 2ⁿ values is [0; 2ⁿ−1], n is an integer.

2. The method according to claim 1, wherein the 2ⁿ values correspond to 2ⁿ first representations in the RNS, the 2n values correspond to 2ⁿ second representations in the CRNS, and the 2ⁿ first representations and the 2ⁿ second representations are in a bijection mapping relationship.

3. The method according to claim 2, wherein the 2ⁿ first representations comprise f first representations of a first type and (2ⁿ−f) first representations of a second type, the truncated bit of the first representation of the first type is equal to one, and the truncated bit of the first representation of the second type is equal to zero;
wherein the f first representations of the first type correspond to f second representations, and each of the f second representations is identical to recoded remaining n bits of the corresponding first representation of the first type that exclude the truncated bit;
wherein the (2ⁿ−f) first representations of the second type correspond to (2ⁿ−f) second representations, and each of the (2ⁿ−f) second representations is identical to the remaining n bits of the corresponding first representation of the second type that exclude the truncated bit.

4. The method according to claim 3, the bijection mapping relationship between the f first representations of the first type and the f second representations is adjustable.

5. The method according to claim 1, wherein the n+1 bits of the first representation comprise k parts, the k parts are residuals corresponding to k moduli of the RNS, and the k parts are arranged in one of the following orders:
in an ascending order according to corresponding values of the k moduli;
in a descending order according to corresponding values of the k moduli; or
in a random order.

6. The method according to claim 5, wherein the k parts comprise a first part, and the first part comprise pᵢ bits, the truncated bit is any one of the pᵢ bits, pᵢ=[log₂(mᵢ−1)], mᵢ is a modulo of the k moduli corresponding to the first part, and the first part is any one of the k parts, 1≤i≤k, i and k are integers.

7. The method according to claim 6, wherein the truncated bit is a most significant bit (MSB) of the pᵢ bits.

8. The method according to claim 7, wherein the mᵢ is being the form mᵢ=2^{q}^{ᵢ}+1, qᵢ is an integer.

9. The method according to claim 8, wherein the mᵢ is the modulo that has the largest value of the k moduli.

10. A chip, comprising:
an input interface, configured to receive a first representation of a first value, wherein the first representation is a representation of the first value in an RNS, and the first representation contains n+1 bits;
a plurality of circuits, configured to:
determine whether a truncated bit of the n+1 bits is equal to zero or one;
convert the first representation to a second representation, wherein the second representation is a representation of the first value in a CRNS, and the second representation contains n bits;
wherein the second representation is identical to remaining n bits of the n+1 bits of the first representation excluding the truncated bit in the case that the truncated bit is equal to zero, and the second representation is identical to recoded remaining bits of the n+1 bits of the first representation excluding the truncated bit in the case that the truncated bit is equal to one; and
the first value is one of 2ⁿ values, the 2ⁿ values can be represented by an n-bit binary number system (BNS), and a value range of the 2ⁿ values is [0; 2ⁿ−1], n is an integer.

11. The chip according to claim 10, wherein the 2ⁿ values correspond to 2ⁿ first representations in the RNS, the 2ⁿ values correspond to 2ⁿ second representations in the CRNS, and the 2ⁿ first representations and the 2ⁿ second representations are in a bijection mapping relationship.

12. The chip according to claim 11, wherein the 2ⁿ first representations comprise f first representations of a first type and (2ⁿ−f) first representations of a second type, the truncated bit of the first representation of the first type is equal to one, and the truncated bit of the first representation of the second type is equal to zero;
wherein the f first representations of the first type correspond to f second representations, and each of the f second representations is identical to recoded remaining n bits of the corresponding first representation of the first type that exclude the truncated bit;
wherein the (2ⁿ−f) first representations of the second type correspond to (2ⁿ−f) second representations, and each of the (2ⁿ−f) second representations is identical to the remaining n bits of the corresponding first representation of the second type that exclude the truncated bit.

13. The chip according to claim 12, the bijection mapping relationship between the f first representations of the first type and the f second representations is adjustable.

14. A chip, comprising:
an input interface, configured to receive a second representation of a first value, wherein the second representation is a representation of the first value in a CRNS, and the second representation contains n bits;
a plurality circuits, configured to:
determine whether the second representation is identical in the CRNS and an RNS; and
convert the second representation to a first representation, wherein the first representation is a representation of the first value in the RNS, and the first representation contains n+1 bits;
wherein if the second representation is identical in the CRNS and the RNS, the first representation is identical to the n bits of the second representation and a truncated bit added by zero, and if the second representation is different in the CRNS and the RNS, the first representation is identical to the n bits of the second representation and the truncated bit added by one;
wherein the first value is one of 2ⁿ values, the 2ⁿ values can be represented by an n-bit binary number system (BNS), and a value range of the 2ⁿ values is [0; 2ⁿ−1], n is an integer.

15. The chip according to claim 14, wherein the 2ⁿ values correspond to 2ⁿ second representations in the CRNS, the 2n values correspond to 2ⁿ first representations in the RNS, and the 2ⁿ second representations and the 2ⁿ first representations are in a bijection mapping relationship.

16. The chip according to claim 15, wherein the 2ⁿ first representations comprise f first representations of a first type and (2ⁿ−f) first representations of a second type, the truncated bit of the first representation of the first type is equal to one, and the truncated bit of the first representation of the second type is equal to zero;
wherein the f first representations of the first type correspond to f second representations, and each of the f second representations is identical to recoded remaining n bits of the corresponding first representation of the first type that exclude the truncated bit;
wherein the (2ⁿ−f) first representations of the second type correspond to (2ⁿ−f) second representations, and each of the (2ⁿ−f) second representations is identical to the remaining n bits of the corresponding first representation of the second type that exclude the truncated bit.

17. The chip according to claim 16, wherein the f second representations corresponding to the f first representation of the first type are different in the CRNS and the RNS, and the (2ⁿ−f) second representations corresponding to the (2ⁿ−f) first representation of the second type are identical in the CRNS and the RNS;
wherein the a plurality of circuits are configured to:
determine whether the second representation is identical in the CRNS and the RNS by identifying whether the second representation belongs to the f second representations or not, wherein the f second representations are predetermined.
